(19) United States
(12) Patent Application Publication
(10) Pub. No.: US 2025/0151291 A1
(43) Pub. Date: May 8, 2025

(54) SEMICONDUCTOR MEMORY DEVICE

(71) Applicant: Samsung Electronics Co., Ltd., Suwon-si (KR)

(72) Inventors: KEONWOO PARK, Suwon-si (KR); KYU-CHANG KANG, Suwon-si (KR)

(21) Appl. No.: 18/656,668

(22) Filed: May 7, 2024

(30) Foreign Application Priority Data
Nov. 8, 2023 (KR) 10-2023-0153818

(51) Int. Cl. H10B 80/00; G11C 11/408; H01L 23/00; H01L 25/065; H01L 25/18; H10B 12/00

(52) U.S. Cl. CPC H10B 80/00; G11C 11/4085; H01L 24/08; H01L 25/0657; H01L 25/18; H10B 12/315; H10B 12/50; H01L 2224/08145; H01L 2924/1431; H01L 2924/1436

(57) ABSTRACT

A semiconductor memory device includes a first chip and a second chip. The first chip includes a first cell array mat and a second cell array mat adjacent to the first cell array mat. The second chip has a stacked structure with the first chip and includes a first sub-word line driver configured to generate a first drive signal applied to the first word lines from one side of each of the first and second cell array mats, and a second sub-word line driver configured to generate a second drive signal applied to the second word lines from an opposite side of each of the first and second cell array mats.

### CROSS-REFERENCE TO RELATED APPLICATION(S)

This application claims priority under 35 U.S.C. § 119 to Korean Patent Application No. 10-2023-0153818 filed on Nov. 8, 2023, in the Korean Intellectual Property Office, the disclosure of which is incorporated by reference herein in its entirety.

### BACKGROUND

Embodiments of the present disclosure described herein relate to a semiconductor memory device.

Semiconductor memory devices are used to store data. The semiconductor memory devices are classified into volatile memory devices and non-volatile memory devices. The volatile memory devices are memory devices in which stored data is lost when the supply of power is cut off. Among the volatile memory devices, dynamic random access memory (DRAM) is used in various fields such as mobile systems, servers, graphic devices, and the like.

The DRAM basically performs word line-level operations when writing data to memory cells or reading the data from the memory cells. A plurality of memory cells are connected to one word line, and as the number of connected memory cells is increased, word line loading is increased.

### SUMMARY

Embodiments of the present disclosure provide a semiconductor memory device for improving the performance thereof by appropriately arranging sub-word line drivers using a cell on periphery (CoP) structure.

According to an embodiment, a semiconductor memory device includes a first chip and a second chip. The first chip includes a first cell array mat and a second cell array mat adjacent to the first cell array mat, and each of the first and second cell array mats includes first word lines and second word lines. The second chip includes a stacked structure with the first chip, a first sub-word line driver configured to generate a first drive signal applied to the first word lines from one side of each of the first and second cell array mats, and a second sub-word line driver configured to generate a second drive signal applied to the second word lines from an opposite side of each of the first and second cell array mats.

According to an embodiment, a semiconductor memory device includes a plurality of cell array mats implemented in a first chip, each cell array mat including a plurality of word lines and a plurality of sub-word line drivers implemented in a second chip having a stacked structure with the first chip and disposed to correspond to the plurality of cell array mats, respectively. The plurality of sub-word line drivers generate drive signals applied to the plurality of word lines of the plurality of cell array mats. A first drive signal of the drive signals is applied to even word lines among the plurality of word lines from one side of a corresponding cell array mat, and a second drive signal of the drive signals is applied to odd word lines among the plurality of word lines from an opposite side of the corresponding cell array mat.

According to an embodiment, a semiconductor memory device having a cell on periphery (CoP) structure includes a first chip including a plurality of cell array mats, each of which includes a plurality of word lines and a second chip including a plurality of sub-word line drivers disposed under the plurality of cell array mats, respectively. The plurality of sub-word line drivers are configured to generate drive signals. The plurality of word lines include even word lines to which a first drive signal of the drive signals is applied from one side of a corresponding cell array mat and odd word lines to which a second drive signal of the drive signals is applied from an opposite side of the corresponding cell array mat. The plurality of sub-word line drivers include first and second sub-word line drivers corresponding to two adjacent cell array mats configured to respectively generate the first drive signal applied to the even word lines of the two adjacent cell array mats and the second drive signal applied to the odd word lines of the two adjacent cell array mats.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a configuration of a semiconductor memory device according to an embodiment of the present disclosure.

FIG. 2A is a view illustrating the layout of a semiconductor memory device.

FIG. 2B is a view illustrating the layout of the semiconductor memory device according to an embodiment of the present disclosure.

FIG. 3A is a schematic plan view illustrating a portion of a semiconductor memory device.

FIG. 3B is a sectional view corresponding to the plan view of FIG. 3A.

FIG. 4A is a schematic plan view illustrating a portion of a semiconductor memory device according to an embodiment of the present disclosure.

FIG. 4B is a sectional view corresponding to the plan view of FIG. 4A according to example embodiments.

FIG. 5 is a schematic sectional view illustrating a portion of a semiconductor memory device according to an embodiment of the present disclosure.

FIG. 6 is a block diagram illustrating a configuration of a semiconductor memory system according to an embodiment of the present disclosure.

FIG. 7 is a block diagram illustrating a configuration of a semiconductor memory device according to an embodiment of the present disclosure.

FIG. 8 is a view illustrating a configuration of a cell array mat according to an embodiment of the present disclosure.

FIG. 9A is a view illustrating the layout of a cell array mat according to an embodiment of the present disclosure.

FIG. 9B is a perspective view illustrating the cell array mat of FIG. 9A according to example embodiments.

FIG. 9C illustrates sectional views taken along lines X-X1′ and Y-Y1′ of FIG. 9A according to example embodiments.

FIG. 9D is a view illustrating the layout of a cell array mat according to an embodiment of the present disclosure.

FIG. 9E is a perspective view illustrating the cell array mat of FIG. 9D according to example embodiments.

FIG. 10A is a schematic plan view illustrating a portion of a semiconductor memory device according to an embodiment of the present disclosure.

FIG. 10B is a sectional view corresponding to the plan view of FIG. 10A according to example embodiments.

### DETAILED DESCRIPTION

In some aspects, a number of memory cells connected to one word line may be increased based on increased degree of integration of memory cells, and a word line driver handling the word line may be affected from the increased load. In some embodiments, the word line load may be shared by using a plurality of sub-word line drivers that is distributed in a memory cell array.

Hereinafter, embodiments of the present disclosure will be described in detail with reference to the accompanying drawings such that those skilled in the art to which the present disclosure pertains are able to readily carry out the present disclosure.

The terms, such as “first”, “second”, and the like used herein may be used to refer to various components regardless of the order and/or the priority and to distinguish the relevant components from other components, but do not limit the components.

Hereinafter, a first wafer on which memory cells are disposed may be referred to as a first chip. In addition, a second wafer on which various circuits for driving the memory cells are disposed may be referred to as a second chip.

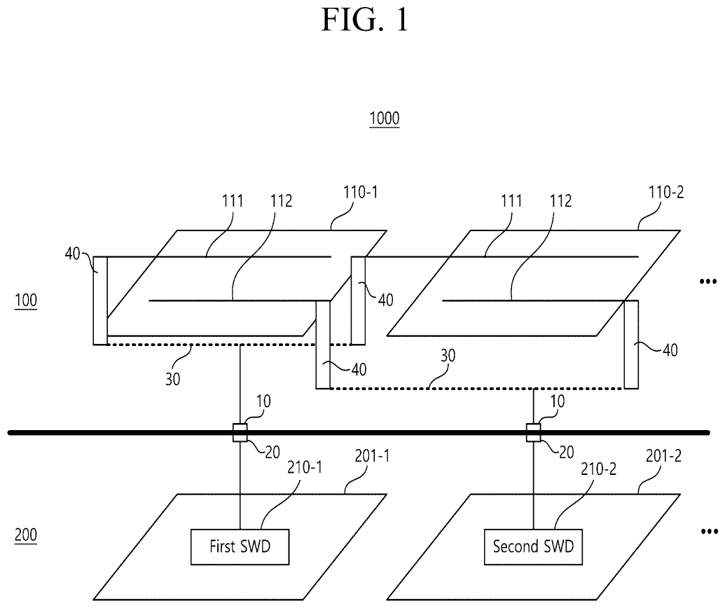

FIG. 1 is a block diagram illustrating a configuration of a semiconductor memory device 1000 according to an embodiment of the present disclosure.

Referring to FIG. 1, the semiconductor memory device 1000 may include the first chip 100 and the second chip 200. The first chip 100 and the second chip 200 may have a stacked structure. For example, the first chip 100 and the second chip 200 may have a cell on periphery (CoP) structure.

The CoP structure may be a structure in which the first wafer including the memory cells and the second wafer including core circuits and peripheral circuits are separately manufactured and thereafter the first wafer is stacked on and bonded to the second wafer. In this specification, the first wafer on which the memory cells are disposed and the second wafer on which the core circuits and the peripheral circuits are disposed may be referred to as the first chip and the second chip, respectively.

In an embodiment, the first chip 100 and the second chip 200 that have the CoP structure may be electrically connected to each other by bonding first bonding metals 10 formed at the bottom of the first chip 100 and second bonding metals 20 formed at the top of the second chip 200. Alternatively, in some embodiments, the first chip 100 and the second chip 200 that have the CoP structure may be electrically connected to each other through a through substrate via (e.g., through silicon via (TSV)) method.

The first chip 100 may include a memory cell array. The memory cell array may include a plurality of memory cells formed at intersections of word lines and bit lines. The memory cell array may be divided into a plurality of cell array mats. The memory cell array may be divided into areas that respective sub-word line drivers are in charge of. The areas of the memory cell array divided from one another may be the cell array mats, respectively.

According to an embodiment, the first chip 100 may include a first cell array mat 110-1 and a second cell array mat 110-2 adjacent to the first cell array mat 110-1. Each of the first cell array mat 110-1 and the second cell array mat 110-2 may include first word lines 111 to which a drive signal is applied from one side of a corresponding cell array mat and second word lines 112 to which a drive signal is applied from an opposite side of the corresponding cell array mat.

In an embodiment, the one side and the opposite side may be the left side and the right side, respectively. Alternatively, in some embodiments, the one side and the opposite side may be an upper side and a lower side, respectively. In addition, in an embodiment, the first word lines 111 and the second word lines 112 may be even word lines and odd word lines, respectively, but are not limited thereto.

In FIG. 1, only one first word line 111 and one second word line 112 are illustrated on each of the cell array mats 110-1 and 110-2. However, this is only for convenience of illustration, and each of the cell array mats 110-1 and 110-2 may include a plurality of first word lines 111 and a plurality of second word lines 112.

The second chip 200 may include various circuits for driving the memory cell array of the first chip 100. For example, the second chip 200 may include various core circuits such as a bit line sense amplifier, a sub-word line driver, a row decoder (or, an X-decoder), a column decoder (or, a Y-decoder), and the like. In addition, the second chip 200 may include various peripheral circuits such as a control logic circuit for decoding commands, an address register, a delayed locked loop (DLL), a data I/O buffer, a power circuit, and the like.

According to an embodiment, the second chip 200 may include a plurality of sub-word line drivers that correspond to the plurality of cell array mats, respectively. According to an embodiment, the plurality of sub-word line drivers may be disposed under the corresponding cell array mats, respectively.

For example, referring to FIG. 1, the second chip 200 may include a first sub-word line driver 210-1 corresponding to the first cell array mat 110-1 and a second sub-word line driver 210-2 corresponding to the second cell array mat 110-2. The first and second sub-word line drivers 210-1 and 210-2 may be located under the first and second cell array mats 110-1 and 110-2, respectively. In an embodiment, the first sub-word line driver 210-1 may be disposed in a portion of an area 201-1 of the second chip 200 that overlaps the area of the first chip 100 where the first cell array mat 110-1 is formed. In addition, the second sub-word line driver 210-2 may be disposed in a portion of an area 201-2 of the second chip 200 that overlaps the area of the first chip 100 where the second cell array mat 110-2 is formed.

According to an embodiment of the present disclosure, the first sub-word line driver 210-1 may generate the drive signal applied to the first word lines 111 of the first and second cell array mats 110-1 and 110-2. In addition, the second sub-word line driver 210-2 may generate the drive signal applied to the second word lines 112 of the first and second cell array mats 110-1 and 110-2.

In this case, for example, the drive signal generated by the first sub-word line driver 210-1 may be transferred to the first chip 100 through a first bonding metal 10 and a second bonding metal 20 and may be transferred to the opposite sides of the first cell array mat 110-1 through a lower metal layer 30 of the first chip 100. In an embodiment, the lower metal layer 30 may be formed below the first and second cell array mats 110-1 and 110-2. The drive signal transferred to the opposite sides of the first cell array mat 110-1 may be applied to the first word lines 111 of the first and second cell array mats 110-1 and 110-2 through VIAs 40.

Likewise, the drive signal generated by the second sub-word line driver 210-2 may be transferred to the first chip 100 through a first bonding metal 10 and a second bonding metal 20 and may be transferred to the opposite sides of the second cell array mat 110-2 through a lower metal layer 30 of the first chip 100. The drive signal transferred to the opposite sides of the second cell array mat 110-2 may be applied to the second word lines 112 of the first and second cell array mats 110-1 and 112-2 through VIAs 40.

According to the above-described embodiments of the present disclosure, the sub-word line drivers may be appropriately arranged using the CoP structure. In this case, a gross die gain may be secured, and a word line loading difference between the sub-word line drivers may be eliminated. Accordingly, the performance of the semiconductor memory device 1000 may be improved.

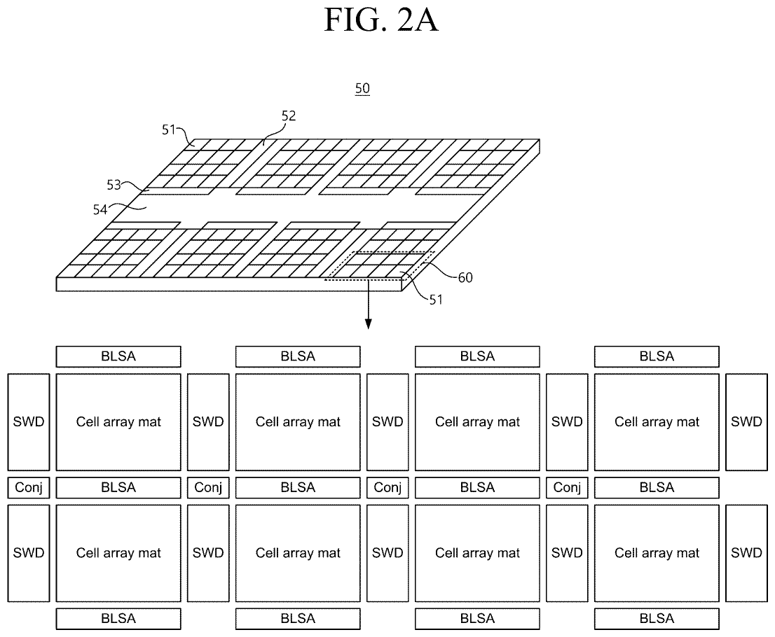

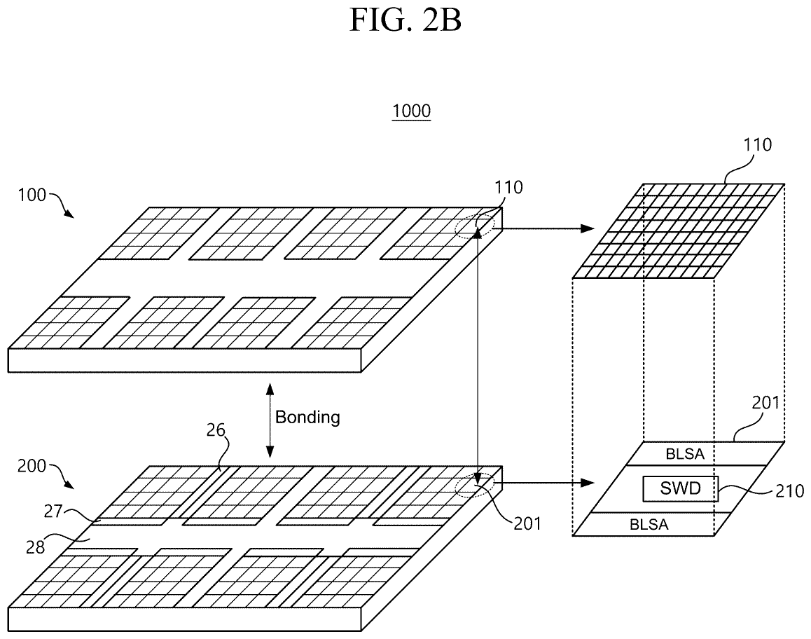

Hereinafter, layouts of semiconductor memory devices will be described with reference to FIGS. 2A and 2B.

FIG. 2A is a view illustrating the layout of a semiconductor memory device. In the semiconductor memory device, a memory cell array, core circuits, and peripheral circuits may be implemented in one chip 50.

Referring to FIG. 2A, a unit core including a cell array mat having a certain size, a sub-word line driver SWD, a bit line sense amplifier BLSA, and a conjunction area Conj may be disposed in a first area 51 of the chip 50. Unit cores may be arranged in a matrix form in the chip 50. For example, an enlarged view of one area 60 of the chip 50 is illustrated below the arrow. Specifically, in a first direction, a plurality of sub-word line drivers SWD may be disposed between a plurality of cell array mats, and in a second direction, a plurality of bit line sense amplifiers BLSA may be disposed between the cell array mats. Conjunction areas Conj may be disposed between the plurality of sub-word line drivers SWD in the second direction and between the plurality of bit line sense amplifiers BLSA in the first direction.

Meanwhile, a row decoder may be disposed in a second area 52 of the chip 50, and a column decoder may be disposed in a third area 53 of the chip 50. In addition, various peripheral circuits, such as a control logic circuit, an address register, a DLL, a data I/O buffer, a power circuit, and the like, may be disposed in a fourth area 54.

FIG. 2B is a view illustrating a layout of the semiconductor memory device according to an embodiment of the present disclosure. Referring to FIG. 2B, the semiconductor memory device 1000 may have a CoP structure in which the first chip 100 in which the memory cells are implemented and the second chip 200 in which the core circuits and the peripheral circuits are implemented are bonded to each other.

The first chip 100 may include a plurality of cell array mats 110. When compared to the first area 51 in which the unit core of FIG. 2A is disposed, each cell array mat 110 of the first chip 100 may not have a sub-word line driver SWD, a bit line sense amplifier BLSA, and a conjunction area Conj around the cell array mat 110.

In this case, a sub-word line driver SWD, a bit line sense amplifier BLSA, and a conjunction area Conj for driving each cell array mat 110 may be disposed in a first area 201 of the second chip 200. For example, as illustrated in FIG. 2B, the bit line sense amplifier BLSA and the sub-word line driver SWD 210 for driving the cell array mat 110 may be disposed in the first area 201 of the second chip 200 that corresponds to a corresponding cell array mat 110. In particular, according to an embodiment of the present disclosure, the sub-word line driver 210 corresponding to the relevant cell array mat 110 may be disposed in a portion of the first area 201 of the second chip 200 that overlaps an area in which the corresponding cell array mat 110 is formed.

Meanwhile, according to an embodiment of the present disclosure, a row decoder may be disposed in a second area 26 of the second chip 200, and a column decoder may be disposed in a third area 27 of the second chip 200. In addition, various peripheral circuits, such as a control logic circuit, an address register, a DLL, a data I/O buffer, a power circuit, and the like, may be disposed in a fourth area 28 of the second chip 200.

In FIG. 2B, the cell array mats, the core circuits, and the peripheral circuits are illustrated in the same form as that in FIG. 2A. However, this is merely an example for comparison with the layout of the semiconductor memory device, and the layout of the semiconductor memory device 1000 according to an embodiment of the present disclosure is not limited to that illustrated in FIG. 2B. For example, when compared to the chip 50 of FIG. 2A, the first chip 100 of the semiconductor memory device 1000 may have a space in which the sub-word line driver SWD, the bit line sense amplifier BLSA, the row decoder, and the column decoder do not exist. Accordingly, a layout different from that illustrated in the drawing may be possible, such as increasing the sizes of the cell array mats using the corresponding space.

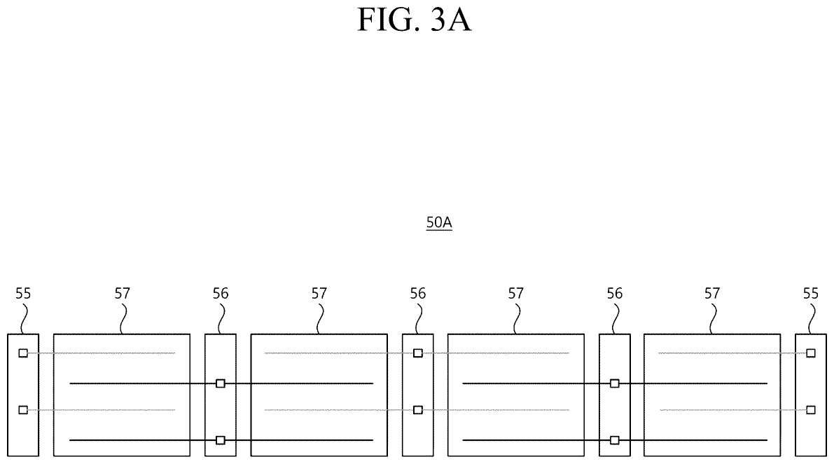

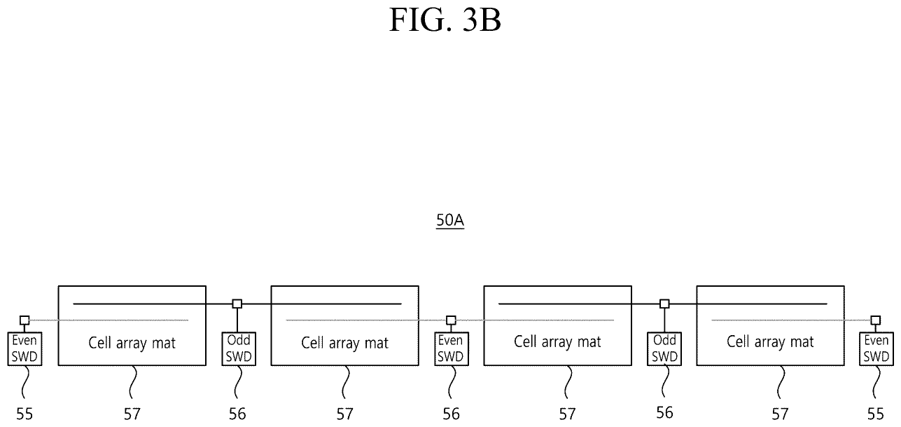

FIGS. 3A and 3B are views for explaining a configuration and an operation of a semiconductor memory device 50A. FIG. 3A is a schematic plan view illustrating a portion of the semiconductor memory device 50A, and FIG. 3B is a sectional view corresponding to the plan view of FIG. 3A.

Referring to FIGS. 3A and 3B together, in the semiconductor memory device 50A, sub-word line drivers 55 and 56 are located on the same plane as cell array mats 57. That is, in the semiconductor memory device 50A, the cell array mats 57 and the sub-word line drivers 55 and 56 are implemented together on one wafer (or, chip). In addition, in the semiconductor memory device 50A, each of the sub-word line drivers 55 and 56 is disposed between the cell array mats 57 to appropriately distribute word line loading and increase area efficiency.

The sub-word line drivers 56 arranged in the central area of the cell array mats have an even/odd double-arm word line structure. Here, the even/odd double-arm word line structure refers to a structure in which the sub-word line driver 56 is in charge of even word lines or odd word lines of two adjacent cell array mats. Meanwhile, the sub-word line drivers 55 disposed in edge areas of the cell array are in charge of only even or odd word lines of one cell array mat.

In this case, the sub-word line drivers 56 arranged in the central areas and the sub-word line drivers 55 disposed in the edge areas differ from each other in terms of the number of word lines that the sub-word line drivers are in charge of, that is, the number of memory cells that the sub-word line drivers are in charge of, and therefore there is a difference in word line loading. The difference in word line loading may cause a difference in driving time between memory cells connected to word lines having the same row address.

To eliminate the aforementioned difference in driving time, the driving performance of the sub-word line drivers 55 and 56 may be adjusted overall by reducing the sizes of the sub-word line drivers 55 disposed in the edge areas where word line loading is relatively small. However, this increases the complexity of design and lowers the overall driving performance of the sub-word line drivers, which limits the performance improvement of the semiconductor memory device.

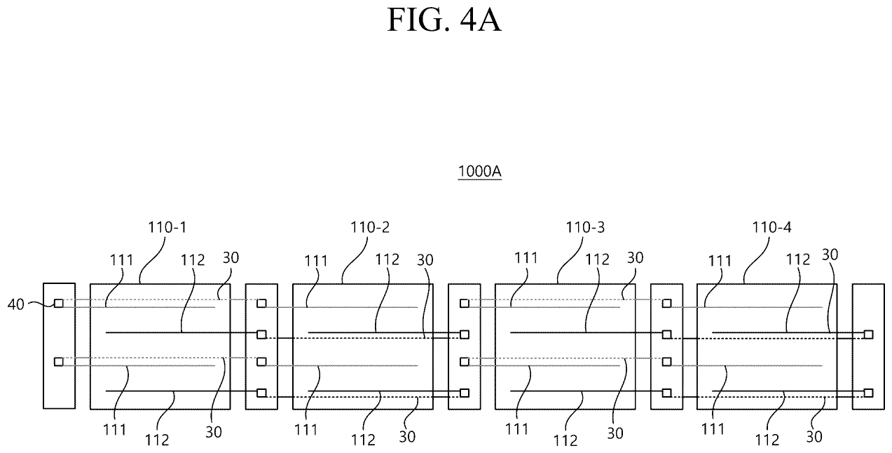

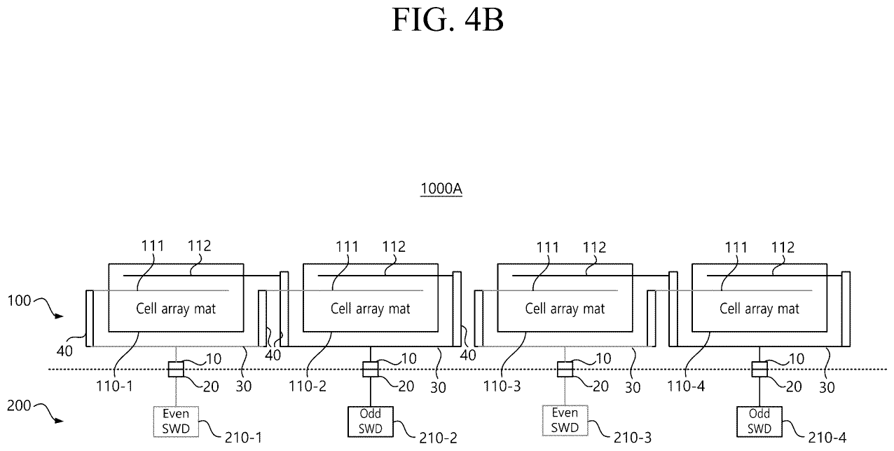

FIGS. 4A and 4B are views for explaining a configuration and an operation of a semiconductor memory device according to an embodiment of the present disclosure. FIG. 4A is a schematic plan view illustrating a portion of the semiconductor memory device 1000A according to an embodiment of the present disclosure, and FIG. 4B is a sectional view corresponding to the plan view of FIG. 4A according to example embodiments. The semiconductor memory device 1000A may be an implemented embodiment of the semiconductor memory device 1000 of FIGS. 1 and 2B. However, the present disclosure is not limited thereto.

Referring to FIGS. 4A and 4B, the semiconductor memory device 1000A may include a first cell array mat 110-1, a second cell array mat 110-2, a third cell array mat 110-3, and a fourth cell array mat 110-4. In addition, the semiconductor memory device 1000A may include a first sub-word line driver 210-1 disposed under the first cell array mat 110-1, a second sub-word line driver 210-2 disposed under the second cell array mat 110-2, a third sub-word line driver 210-3 disposed under the third cell array mat 110-3, and a fourth sub-word line driver 210-4 disposed under the fourth cell array mat 110-4.

The first to fourth cell array mats 110-1, 110-2, 110-3, and 110-4 may be included in a first chip 100, and the first to fourth sub-word line drivers 210-1, 210-2, 210-3, and 210-4 may be included in a second chip 200. The first chip 100 and the second chip 200 may have a CoP structure in which the first chip 100 is stacked on the second chip 200. According to an embodiment, the first chip 100 and the second chip 200 may be electrically connected to each other by bonding first bonding metals 10 formed at the bottom of the first chip 100 and second bonding metals 20 formed at the top of the second chip 200.

Each of the first to fourth cell array mats 110-1 to 110-4 may include first word lines 111 to which a drive signal is applied from one side of a corresponding cell array mat and second word lines 112 to which a drive signal is applied from an opposite side of the corresponding cell array mat. The first word lines 111 and the second word lines 112 may be alternately arranged on the corresponding cell array mat. In an embodiment, the first word lines 111 may be even word lines, and the second word lines 112 may be odd word lines. However, the present disclosure is not limited thereto.

The first to fourth sub-word line drivers 210-1, 210-2, 210-3, and 210-4 may generate drive signals applied to the first to fourth cell array mats 110-1, 110-2, 110-3, and 110-4. The first to fourth sub-word line drivers 210-1, 210-2, 210-3, and 210-4 may include, for example, even sub-word line drivers 210-1 and 210-3 that generate drive signals applied to the even word lines 111 and odd sub-word line drivers 210-2 and 210-4 that generate drive signals applied to the odd word lines 112.

According to an embodiment of the present disclosure, among the plurality of sub-word line drivers, two sub-word line drivers corresponding to two adjacent cell array mats may generate a drive signal applied to even word lines of the two adjacent cell array mats and a drive signal applied to odd word lines of the two adjacent cell array mats. In an embodiment, each of the sub-word line drivers may generate a drive signal applied to even word lines of the plurality of cell array mats in response to a first row address, and each of the sub-word line drivers may generate a drive signal applied to odd word lines of the plurality of cell array mats in response to a second row address.

For example, the first and second sub-word line drivers 210-1 and 210-2 corresponding to the first and second cell array mats 110-1 and 110-2 adjacent to each other may generate a drive signal applied to the even word lines 111 of the first and second cell array mats 110-1 and 110-2 and a drive signal applied to the odd word lines 112 of the first and second cell array mats 110-1 and 110-2. In addition, the third and fourth sub-word line drivers 210-3 and 210-4 corresponding to the third and fourth cell array mats 110-3 and 110-4 adjacent to each other may generate a drive signal applied to the even word lines 110 of the third and fourth cell array mats 110-3 and 110-4 and a drive signal applied to the odd word lines 112 of the third and fourth cell array mats 110-3 and 110-4.

Meanwhile, the drive signals generated by the first to fourth sub-word line drivers 210-1, 210-2, 210-3, and 210-4 may be transferred to the first chip 100 through the first and second bonding metals 10 and 20 and thereafter may be applied to the word lines to which the drive signals have to be applied.

Specifically, the drive signal generated from the first sub-word line driver 210-1 may be transferred to the first chip 100 through the first and second bonding metals 10 and 20. The drive signal transferred to the first chip 100 may be transferred to the opposite sides of the first cell array mat 110-1 through a lower metal layer 30 of the first chip 100. The drive signal transferred to the opposite sides of the first cell array mat 110-1 may be applied to the even word lines 111 of the first and second cell array mats 110-1 and 110-2 through VIAs 40 formed on the opposite sides of the first cell array mat 110-1.

Meanwhile, the drive signal generated from the second sub-word line driver 210-2 may be transferred to the first chip 100 through the first and second bonding metals 10 and 20. The drive signal transferred to the first chip 100 may be transferred to the opposite sides of the second cell array mat 110-2 through a lower metal layer 30 of the first chip 100. The drive signal transferred to the opposite sides of the second cell array mat 110-2 may be applied to the odd word lines 112 of the first and second cell array mats 110-1 and 110-2 through VIAs 40 formed on the opposite sides of the second cell array mat 110-2.

Similarly to those described above, the drive signals generated from the third and fourth sub-word line drivers 210-3 and 210-4 may be applied to the even word lines 111 and the odd word lines 112 of the third and fourth cell array mats 110-3 and 110-4, respectively.

According to the embodiments of the present disclosure described above, since the sub-word line drivers 210-1, 210-2, 210-3, and 210-4 are located under the corresponding cell array mats, respectively, outputs of the sub-word line drivers may be connected to the opposite sides of the cell array mats unlike in the semiconductor memory device 50A of FIGS. 3A and 3B. In this case, additional sub-word line drivers are not necessary in the edge areas, and therefore a gross die gain may be obtained. The performance of the semiconductor memory device 1000A may be improved by using the secured additional space in various ways. For example, the performance of the semiconductor memory device 1000A may be improved by increasing the sizes of the sub-word line drivers or bit line sense amplifiers or adding a power circuit used for core circuits.

In addition, according to the embodiments of the present disclosure described above, unlike in the semiconductor memory device 50A of FIGS. 3A and 3B, a drive signal may be applied to the even word lines of each cell array mat from the one side (e.g., left side) of the corresponding cell array mat, and a drive signal may be applied to the odd word lines of each cell array mat from the opposite side (e.g., right side) of the corresponding cell array mat. For example, in all of the cell array mats, the even word lines or the odd word lines may be configured in the same direction. In this case, each of the sub-word line drivers 210-1, 201-2, 210-3, and 210-4 may be connected to two cell array mats, and thus a difference in word line loading between the sub-word line drivers may be eliminated. For example, all of the sub-word line drivers may have the same word line loading. Accordingly, the semiconductor memory device 1000A may have lower design complexity than the semiconductor memory device 50A and may enhance the overall driving performance of the sub-word line drivers 210-1, 210-2, 210-3, and 210-4.

Meanwhile, in FIGS. 4A and 4B, for convenience of description, the four cell array mats 110-1, 110-2, 110-3, and 110-4 and the four sub-word line drivers 210-1, 210-2, 210-3, and 210-4 for driving the four cell array mats 110-1, 110-2, 110-3, and 110-4 are illustrated. However, the numbers of cell array mats and sub-word line drivers included in the semiconductor memory device 1000A are not limited thereto.

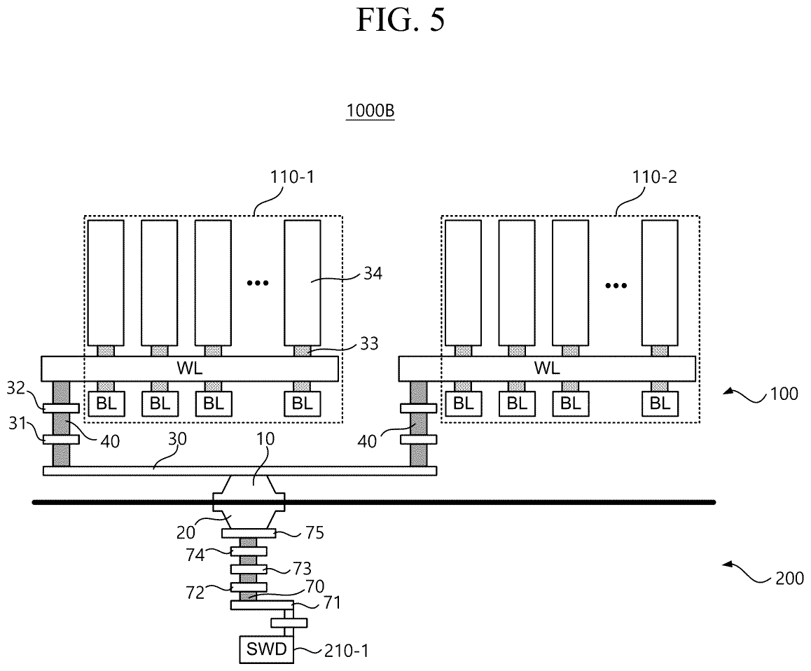

FIG. 5 is a schematic sectional view illustrating a portion of a semiconductor memory device 1000B according to an embodiment of the present disclosure. The semiconductor memory device 1000B may be an implemented embodiment of the semiconductor memory devices 1000 and 1000A of FIGS. 1, 2B, 4A, and 4B. However, the present disclosure is not limited thereto.

Referring to FIG. 5, the semiconductor memory device 1000B may include a first chip 100 and a second chip 200. The first chip 100 and the second chip 200 may have a CoP structure in which the first chip 100 is stacked on the second chip 200. According to an embodiment, the first chip 100 and the second chip 200 may be electrically connected to each other by bonding a first bonding metal 10 formed at the bottom of the first chip 100 and a second bonding metal 20 formed at the top of the second chip 200. The materials of the first and second bonding metals 10 and 20 may include or be formed of copper (Cu). In this case, a bonding method of the first chip 100 and the second chip 200 may be called a Cu—Cu bonding method. However, the present disclosure is not limited thereto, and in some embodiments, the first and second bonding metals 10 and 20 may include or be formed of another metallic material such as aluminum (Al) or tungsten (W).

The first chip 100 may include a plurality of cell array mats. For example, the first chip 100 may include a first cell array mat 110-1 and a second cell array mat 110-2 adjacent to the first cell array mat 110-1. Each of the cell array mats 110-1 and 110-2 may include a plurality of memory cells formed at the intersections of a plurality of word lines WL and a plurality of bit lines BL. According to an embodiment, each of the memory cells may be a DRAM memory cell including a vertical channel transistor 33 and a capacitor 34, but is not limited thereto. As described above, each of the cell array mats 110-1 and 110-2 may include first word lines 111 to which a drive signal is applied from one side of a corresponding cell array mat and second word lines 112 to which a drive signal is applied from an opposite side of the corresponding cell array mat. However, since FIG. 5 is a sectional view, only one word line WL included in each of the first and second cell array mats 110-1 and 110-2 is illustrated.

According to an embodiment of the present disclosure, the first chip 100 may include a metal layer 30 formed below the cell array mats 110-1 and 110-2, and metal layers 31 and 32 formed on the opposite sides of the first cell array mat 110-1. A drive signal transferred to the first chip 100 through the first and second bonding metals 10 and 20 may be transferred to VIAs 40 formed on the opposite sides of the first cell array mat 110-1 through at least one metal layer among the plurality of metal layers 30, 31, and 32. Although FIG. 5 illustrates an example that the drive signal is transferred to the VIAs 40 through the lowermost metal layer 30 among the plurality of metal layers 30, 31, and 32, the present disclosure is not limited thereto. In some embodiments, the drive signal may be transferred to the VIAs 40 through at least one of the other metal layers 31 and 32. In addition, a layer used as a signal transfer path for the word line WL or a layer used as a signal transfer path for the bit line BL is also not limited to that illustrated in FIG. 5, and in some embodiments, other layers may be used.

The plurality of metal layers 30, 31, and 32 may include metal layers formed of various materials, such as an aluminum layer, a copper layer, a tungsten layer, and the like. In an embodiment, the drive signal may be transferred to the VIAs 40 through the tungsten layer 30. However, the present disclosure is not limited thereto.

The drive signal transferred to the VIAs 40 formed on the opposite sides of the first cell array mat 110-1 may be applied to the word lines WL of the first and second cell array mats 110-1 and 110-2.

The second chip 200 may include a plurality of sub-word line drivers that are disposed under the plurality of cell array mats, respectively. According to an embodiment, among the plurality of sub-word line drivers, two sub-word line drivers corresponding to two adjacent cell array mats may generate a drive signal applied to even word lines of the two adjacent cell array mats and a drive signal applied to odd word lines of the two adjacent cell array mats. In an embodiment, unlike the memory cells of the first chip 100, the plurality of sub-word line drivers may be implemented to include a horizontal channel transistor, but are not limited thereto.

Referring to FIG. 5, the second chip 200 may include a sub-word line driver 210-1 disposed under the first cell array mat 110-1. The sub-word line driver 210-1 may generate a drive signal applied to even word lines or odd word lines of the first cell array mat 110-1 and the second cell array mat 110-2.

The drive signal generated by the sub-word line driver 210-1 may be transferred to the second bonding metal 20 through a plurality of metal layers 71, 72, 73, 74, and 75 and a VIA 70 penetrating the metal layers 72, 73, and 74 formed over the sub-word line driver 210-1.

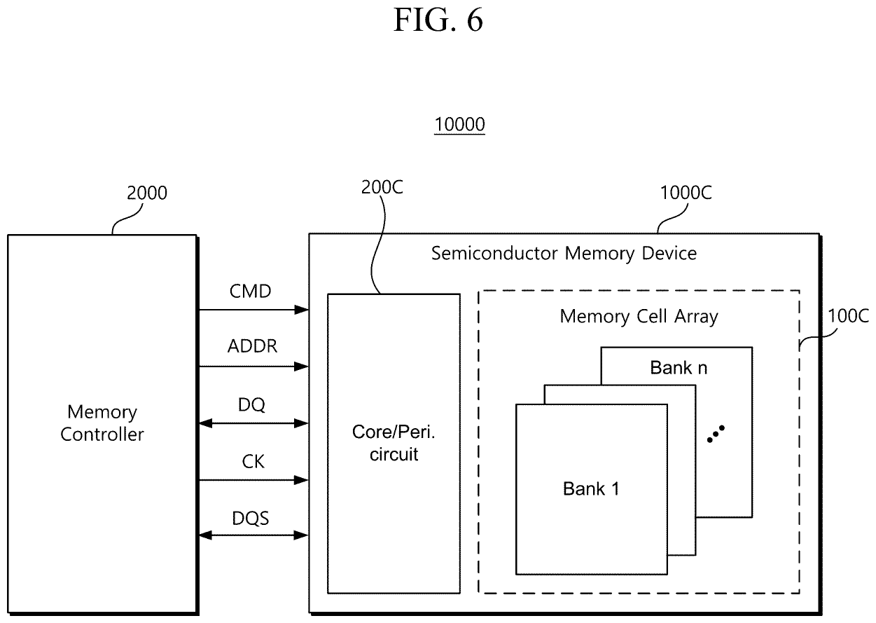

FIG. 6 is a block diagram illustrating a configuration of a semiconductor memory system 10000 according to an embodiment of the present disclosure. Referring to FIG. 6, the semiconductor memory system 10000 may include a memory controller 2000 and a semiconductor memory device 1000C. The semiconductor memory device 1000C may be an example of the semiconductor memory devices 1000, 1000A, and 1000B of FIGS. 1, 2B, 4A, 4B, and 5. However, the present disclosure is not limited thereto.

The memory controller 2000 may control the semiconductor memory device 1000C. For example, the memory controller 2000 may control the semiconductor memory device 1000C in response to a request of a processor that supports various applications such as a server application, a personal computer (PC) application, a mobile application, and the like. For example, the memory controller 2000 may be included in a host including the processor and may control the semiconductor memory device 1000C in response to the request of the processor.

The memory controller 2000 may transmit a clock signal CK, a command CMD, and/or an address ADDR to the semiconductor memory device 1000C to control the semiconductor memory device 1000C. In addition, the memory controller 2000 may transmit a data signal DQ to the semiconductor memory device 1000C, or may receive the data signal DQ from the semiconductor memory device 1000C. The memory controller 2000 may receive a data strobe signal DQS from the semiconductor memory device 1000C when reading the data signal DQ from the semiconductor memory device 1000C. The memory controller 2000 may transmit the data strobe signal DQS to the semiconductor memory device 1000C when writing the data signal DQ to the semiconductor memory device 1000C.

The semiconductor memory device 1000C may receive data from the memory controller 2000 and may store the received data. The semiconductor memory device 1000C may read the stored data in response to a request from the memory controller 2000 and may transmit the data to the memory controller 2000.

In an embodiment, the semiconductor memory device 1000C may be a semiconductor memory device including volatile memory cells. For example, the semiconductor memory device 1000C may include various DRAM devices such as double data rate synchronous dynamic random access memory (DDR SDRAM), DDR2 SDRAM, DDR3 SDRAM, DDR4 SDRAM, DDR5 SDRAM, DDR6 SDRAM, low power double data rate (LPDDR) SDRAM, LPDDR2 SDRAM, LPDDR3 SDRAM, LPDDR4 SDRAM, LPDDR4X SDRAM, LPDDR5 SDRAM, graphics double data rate synchronous graphics random access memory (GDDR SGRAM), GDDR2 SGRAM, GDDR3 SGRAM, GDDR4 SGRAM, GDDR5 SGRAM, GDDR6 SGRAM, and the like.

In an embodiment, the semiconductor memory device 1000C may be a memory device, such as high bandwidth memory (HBM), HBM2, HBM3, or the like, in which DRAM dies or DRAM chips are stacked.

In an embodiment, the semiconductor memory device 1000C may be a memory module such as a dual in-line memory module (DIMM). For example, the semiconductor memory device 1000C may be a registered DIMM (RDIMM), a load reduced DIMM (LRDIMM), an unbuffered DIMM (UDIMM), a fully buffered DIMM (FB-DIMM), or a small outline DIMM (SO-DIMM). However, these are illustrative, and the semiconductor memory device 1000C may be another memory module such as a single in-line memory module (SIMM).

In an embodiment, the semiconductor memory device 1000C may include an SRAM device, a NAND flash memory device, a NOR flash memory device, an RRAM device, an FRAM device, a PRAM device, a TRAM device, an MRAM device, or the like.

The semiconductor memory device 1000C may include a memory cell array 100C and a core/peri circuit 200C. The memory cell array 100C may be implemented in the above-described first chip 100, and the core/peri circuit 200C may be implemented in the above-described second chip 200.

The memory cell array 100C may include a plurality of banks Bank 1 to Bank n, n is a natural number greater than 1, and each of the banks may include memory cells for storing data. For convenience of description, it will be assumed that each bank includes DRAM cells. However, this is illustrative, and each of the plurality of banks Bank 1 to Bank n may be implemented to include volatile memory cells other than the DRAM cells. In addition, each of the plurality of banks Bank 1 to Bank n may be implemented to include the same type of memory cells as each other, or may be implemented to include at least one different type of memory cells.

According to an embodiment, each of the plurality of banks Bank 1 to Bank n may include a plurality of cell array mats. The cell array mats may refer to memory cell areas divided from one another based on sub-word line drivers.

The core/peri circuit 200C may include various circuits for driving the memory cell array 100C. For example, the core/peri circuit 200C may include various core circuits such as a bit line sense amplifier, a sub-word line driver, a row decoder (or, an X-decoder), a column decoder (or, a Y-decoder), and the like. In addition, the core/peri circuit 200C may include various peripheral circuits such as a control logic circuit for decoding commands, an address register, a delayed locked loop (DLL), a data I/O buffer, a power circuit, and the like.

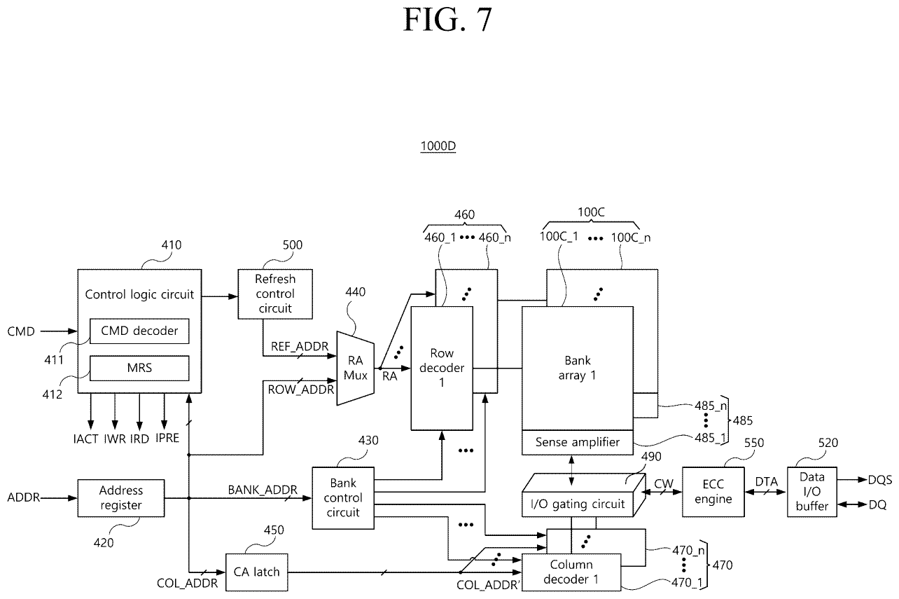

FIG. 7 is a block diagram illustrating a configuration of a semiconductor memory device according to an embodiment of the present disclosure. The semiconductor memory device 1000D may be an example of the semiconductor memory devices 1000, 1000A, 1000B, and 1000C of FIGS. 1, 2B, 4A, 4B, 5, and 6. However, the present disclosure is not limited thereto.

Referring to FIGS. 6 and 7, the semiconductor memory device 1000D may include a control logic circuit 410, an address register 420, a bank control circuit 430, a refresh control circuit 500, a row address multiplexer 440, a column address latch 450, a row decoder 460, a column decoder 470, a memory cell array 100C, a sense amplifier unit 485, an I/O gating circuit 490, an error correction code (ECC) engine 550, and a data I/O buffer 520. In addition, although not illustrated in the drawing, the semiconductor memory device 1000D may include a plurality of sub-word line drivers.

According to an embodiment, the memory cell array 100C may be implemented in the above-described first chip 100. In addition, the remaining circuits 410, 420, 430, 440, 450, 460, 470, 485, 490, 500, 520, and 550 and the plurality of sub-word line drivers (not illustrated) may be implemented in the above-described second chip 200. In an embodiment, referring to FIG. 2B together, the plurality of sub-word line drivers (not illustrated) and the sense amplifier unit 485 may be disposed in the first area 201 of the second chip 200. The row decoder 460 may be disposed in the second area 26 of the second chip 200, and the column decoder 470 may be disposed in the third area 27 of the second chip 200. The control logic circuit 410, the address register 420, the bank control circuit 430, the refresh control circuit 500, the row address multiplexer 440, the column address latch 450, the I/O gating circuit 490, the ECC engine 550, and the data I/O buffer 520 may be disposed in the fourth area 28 of the second chip 200. However, embodiments are not limited thereto.

The memory cell array 100C may include a plurality of bank arrays 100C_1 to 100C_n. Each of the plurality of bank arrays 100C_1 to 100C_n may include a plurality of memory cells. For example, each of the plurality of memory cells may be formed at the intersection of a corresponding word line and a corresponding bit line. Each of the plurality of bank arrays 100C_1 to 100C_n may include a plurality of cell array mats. Herein, n is a natural number greater than 1.

The row decoder 460 may include a plurality of sub-row decoders 460_1 to 460_n. Each of the plurality of sub-row decoders 460_1 to 460_n may be connected to a corresponding bank array among the plurality of bank arrays 100C_1 to 100C_n.

The sense amplifier unit 485 may include a plurality of sense amplifiers 485_1 to 485_n. Each of the plurality of sense amplifiers 485_1 to 485_n may be connected to a corresponding bank array among the plurality of bank arrays 100C_1 to 100C_n.

The column decoder 470 may include a plurality of sub-column decoders 470_1 to 470_n. Each of the plurality of sub-column decoders 470_1 to 470_n may be connected to a corresponding bank array among the plurality of bank arrays 100C_1 to 100C_n through a corresponding sense amplifier.

The plurality of bank arrays 100C_1 to 100C_n, the plurality of sense amplifiers 485_1 to 485_n, the plurality of sub-column decoders 470_1 to 470_n, and the plurality of sub-row decoders 460_1 to 460_n may constitute a plurality of banks. For example, the first bank array 100C_1, the first sense amplifier 485_1, the first sub-column decoder 470_1, and the first sub-row decoder 460_1 may constitute a first bank.

The address register 420 may receive, from a memory controller 2000, an address ADDR including a bank address BANK_ADDR, a row address ROW_ADDR, and a column address COL_ADDR. The address register 420 may provide the received bank address BANK_ADDR to the bank control circuit 430, may provide the received row address ROW_ADDR to the row address multiplexer 440, and may provide the received column address COL_ADDR to the column address latch 450.

The bank control circuit 430 may generate bank control signals in response to the bank address BANK_ADDR. For example, in response to the bank control signals, a row decoder corresponding to the bank address BANK_ADDR among the plurality of sub-row decoders 460_1 to 460_n may be activated. In response to the bank control signals, a column decoder corresponding to the bank address BANK_ADDR among the plurality of sub-column decoders 470_1 to 470_n may be activated.

The row address multiplexer 440 may receive the row address ROW_ADDR from the address register 420 and may receive a refresh row address REF_ADDR from the refresh control circuit 500. The row address multiplexer 440 may selectively output the row address ROW_ADDR or the refresh row address REF_ADDR as a row address RA. The row address RA output from the row address multiplexer 440 may be applied to the plurality of sub-row decoders 460_1 to 460_n.

The refresh control circuit 500 may sequentially increase or decrease the refresh row address REF_ADDR in response to refresh signals from the control logic circuit 410.

Among the plurality of sub-row decoders 460_1 to 460_n, a row decoder selected by the bank control circuit 430 may activate a word line corresponding to the row address RA output from the row address multiplexer 440. For example, the selected row decoder may apply a drive signal to the word line corresponding to the row address RA.

According to an embodiment, the drive signal may be applied to a main word line corresponding to the row address. The drive signal applied to the main word line may be applied to one of the sub-word line drivers above described in FIGS. 1, 2B, 4A, 4B, and 5 for driving the word line corresponding to the row address. Accordingly, the word line corresponding to the relevant row address may be activated by the sub-word line drivers.

The column address latch 450 may receive the column address COL_ADDR from the address register 420 and may temporarily store the received column address COL_ADDR. In addition, for example, in a burst mode, the column address latch 450 may gradually increase the received column address COL_ADDR. The column address latch 450 may apply a temporarily stored or gradually increased column address COL_ADDR′ to the plurality of sub-column decoders 470_1 to 470_n.

Among the plurality of sub-column decoders 470_1 to 470_n, a column decoder activated by the bank control circuit 430 may activate a sense amplifier corresponding to the bank address BANK_ADDR and the column address COL_ADDR through the I/O gating circuit 490.

The I/O gating circuit 490 may include circuits that gate I/O data. In addition, the I/O gating circuit 490 may include data latches for storing a code word CW output from the plurality of bank arrays 100C_1 to 100C_n and write drivers for writing data to the plurality of bank arrays 100C_1 to 100C_n.

In an embodiment, during a read operation, a code word CW read out from a selected bank array among the plurality of bank arrays 100C_1 to 100C_n may be sensed by a sense amplifier corresponding to the selected bank array and may be stored in the data latches of the I/O gating circuit 490. The code word CW stored in the data latches may be ECC decoded by the ECC engine 550 and may be provided to the data I/O buffer 520 as data DTA. The data I/O buffer 520 may generate a data signal DQ based on the data DAT and may provide, to the memory controller 2000, the data signal DQ together with a strobe signal DQS.

In an embodiment, during a write operation, data DAT to be written to a selected bank array among the plurality of bank arrays 100C_1 to 100C_n may be received by the data I/O buffer 520 as a data signal DQ. The data I/O buffer 520 may convert the data signal DQ into the data DTA and may provide the data DTA to the ECC engine 550. The ECC engine 550 may generate parity bits (or, parity data) based on the data DTA and may provide a code word CW including the data DTA and the parity bits to the I/O gating circuit 490. The I/O gating circuit 490 may write the code word CW to the selected bank array.

In the write operation, the data I/O buffer 520 may convert the data signal DQ into the data DTA and may provide the data DTA to the ECC engine 550. In the read operation, the data I/O buffer 520 may convert the data DTA provided from the ECC engine 550 into the data signal DQ.

In the write operation, the ECC engine 550 may perform ECC encoding on the data DTA. In the read operation, the ECC engine 550 may perform ECC decoding on the code word CW.

The control logic circuit 410 may control an operation of the semiconductor memory device 1000D. For example, the control logic circuit 410 may generate control signals such that the semiconductor memory device 1000D performs a write operation, a read operation, and a refresh operation. The control logic circuit 410 may include a command decoder 411 that decodes a command CMD received from the memory controller 2000 and a mode register set MRS 412 for setting an operating mode of the semiconductor memory device 1000D.

The command decoder 411 may decode the command CMD and may generate internal command signals such as an internal active signal IACT, an internal precharge signal IPRE, an internal read signal IRD, an internal write signal IWR, and the like. In addition, the command decoder 411 may decode a chip selection signal and a command/address signal and may generate control signals corresponding to the command CMD.

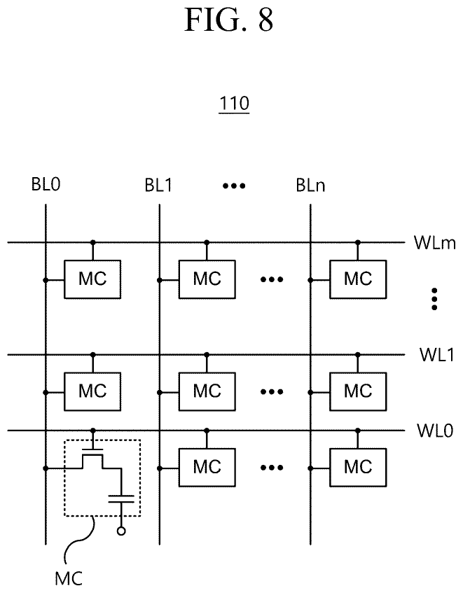

FIG. 8 is a view illustrating a configuration of a cell array mat 110 according to an embodiment of the present disclosure. Referring to FIG. 8, the cell array mat 110 may include a plurality of word lines WL0 to WLm, a plurality of bit lines BL0 to BLn, and a plurality of memory cells MCs disposed at the intersections of the word lines WL0 to WLm and the bit lines BL0 to BLn. Herein, m is a natural number greater than 1.

According to an embodiment, each of the memory cells MC may be a DRAM cell. For example, each of the memory cells MC may include a cell transistor connected to a word line and a bit line and a cell capacitor connected to the cell transistor. According to an embodiment of the present disclosure, the cell transistor may be a vertical channel transistor.

Since a vertical channel transistor has a structure different from that of a horizontal channel transistor, the vertical channel transistor and the horizontal channel transistor may be implemented using different wafers. According to an embodiment of the present disclosure, each memory cell may be implemented using a vertical transistor. In addition, core circuits or peripheral circuits may be implemented using horizontal transistors. According to an embodiment, the memory cells may be implemented in the first chip 100 including vertical channel transistors, and the core circuits or the peripheral circuits may be implemented in the second chip 200 including horizontal channel transistors. Accordingly, the semiconductor memory device 1000 having a CoP structure may be implemented by bonding the first chip 100 and the second chip 200.

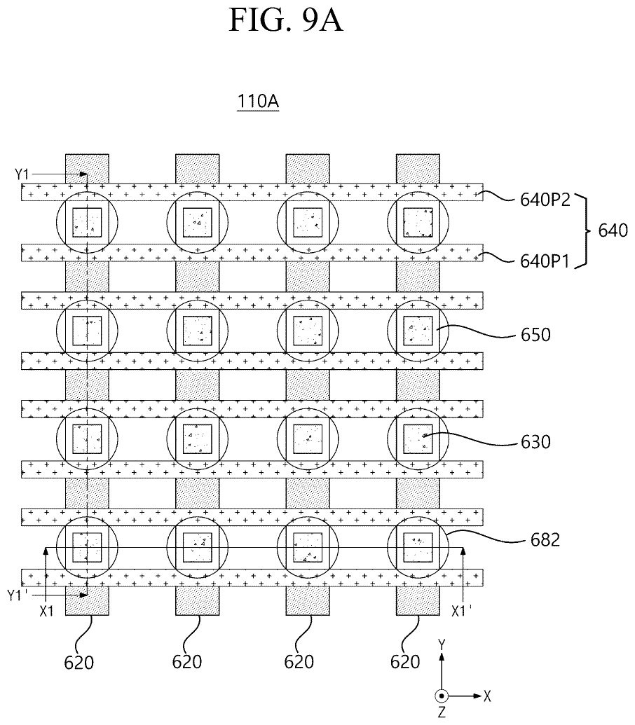

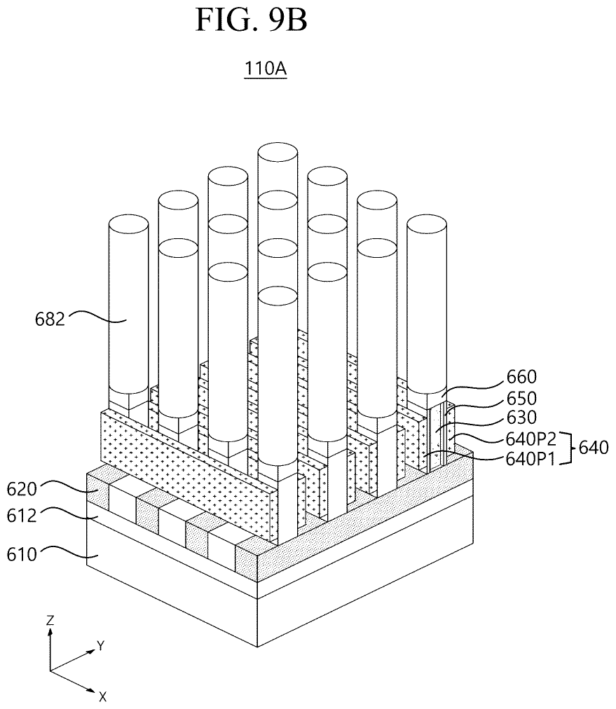

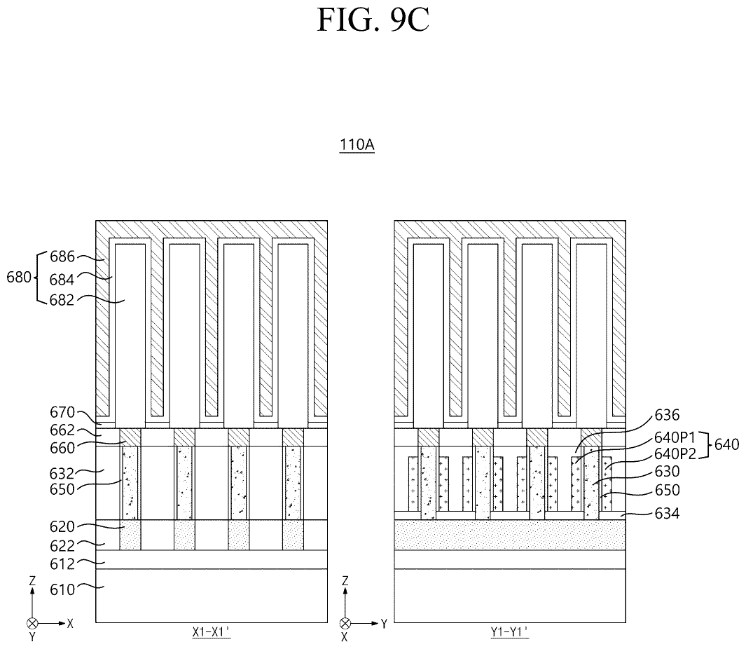

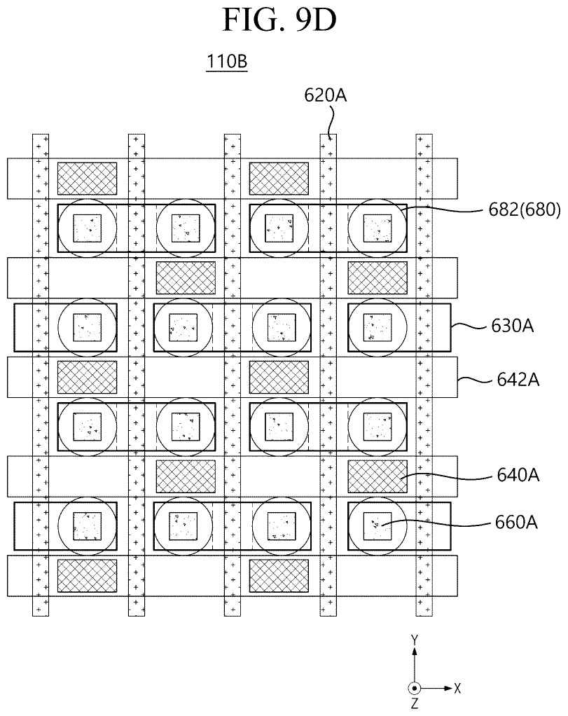

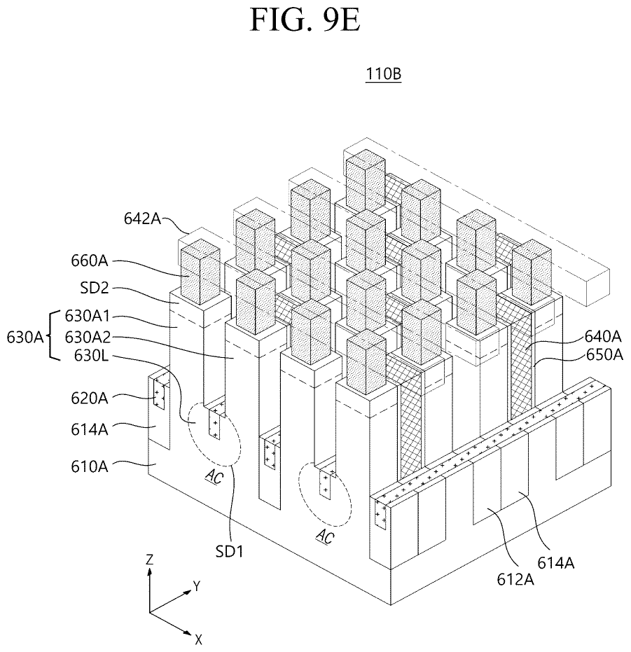

Hereinafter, embodiments of a cell array mat including a vertical channel transistor will be described in more detail with reference to FIGS. 9A to 9E. FIG. 9A is a view illustrating the layout of a cell array mat 110A according to an embodiment of the present disclosure. FIG. 9B is a perspective view illustrating the cell array mat 110A of FIG. 9A according to example embodiments. FIG. 9C illustrates sectional views taken along lines X-X1′ and Y-Y1′ of FIG. 9A according to example embodiments.

Referring to FIGS. 9A to 9C, the cell array mat 110A may include a substrate 610, a plurality of first conductive lines 620, channel layers 630, gate electrodes 640, gate insulating layers 650, and a capacitor structure 680. The cell array mat 110A may include a vertical channel transistor (VCT). The vertical channel transistor may refer to a structure in which the channel lengths of the channel layers 630 extend from the substrate 610 in the vertical direction.

A lower insulating layer 612 may be disposed on the substrate 610, and the plurality of first conductive lines 620 on the lower insulating layer 612 may be spaced apart from each other in a first direction (an X direction) and may extend in a second direction (a Y direction). A plurality of first insulating patterns 622 may be disposed on the lower insulating layer 612 to fill the spaces between the plurality of first conductive lines 620. The plurality of first insulating patterns 622 may extend in the second direction (the Y direction), and the upper surfaces of the plurality of first insulating patterns 622 may be disposed at the same level as the upper surfaces of the plurality of first conductive lines 620. The plurality of first conductive lines 620 may function as bit lines of the cell array mat 110A.

In some embodiments, the plurality of first conductive lines 620 may include doped poly silicon, metal, conductive metal nitride, conductive metal silicide, conductive metal oxide, or a combination thereof. For example, the plurality of first conductive lines 620 may be formed of doped poly silicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but are not limited thereto. The plurality of first conductive lines 620 may include a single layer or multiple layers of the aforementioned materials. In some embodiments, the plurality of first conductive lines 620 may include a two-dimensional semiconductor material. For example, the two-dimensional semiconductor material may include graphene, carbon nanotubes, or a combination thereof.

The channel layers 630 may be arranged in a matrix form on the plurality of first conductive lines 620 so as to be spaced apart from each other in the first direction (the X direction) and the second direction (the Y direction). The channel layers 630 may have a first width in the first direction (the X direction) and a first height in a third direction (a Z direction). The first height may be greater than the first width. For example, the first height may be about two to ten times the first width, but is not limited thereto. A bottom portion of the channel layer 630 may function as a first source/drain area (not illustrated), an upper portion of the channel layer 630 may function as a second source/drain area, and a portion of the channel layer 630 between the first and second source/drain areas may function as a channel area (not illustrated).

In some embodiments, the channel layer 630 may include an oxide semiconductor. For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. The channel layer 630 may include a single layer or multiple layers of the oxide semiconductor. In some embodiments, the channel layer 630 may have band gap energy greater than the ban gap energy of silicon. For example, the channel layer 630 may have a band gap energy of about 1.5 eV to about 5.6 eV. For example, the channel layer 630 may have optimal channel performance when the channel layer 630 has a band gap energy of about 2.0 eV to about 4.0 eV. For example, the channel layer 630 may be polycrystalline or amorphous, but is not limited thereto. In some embodiments, the channel layer 630 may include a two-dimensional semiconductor material. For example, the two-dimensional semiconductor material may include graphene, carbon nanotubes, or a combination thereof.

The gate electrode 640 may extend in the first direction (the X direction) on opposite sidewalls of the channel layer 630. The gate electrode 640 may include a first sub-gate electrode 640P1 facing a first sidewall of the channel layer 630 and a second sub-gate electrode 640P2 facing a second sidewall of the channel layer 630 that faces away from the first sidewall of the channel layer 630. As one channel layer 630 is disposed between the first sub-gate electrode 640P1 and the second sub-gate electrode 640P2, the cell array mat 110A may have a dual gate transistor structure. However, embodiments of the present disclosure are not limited thereto. The second sub-gate electrode 640P2 may be omitted, and only the first sub-gate electrode 640P1 facing the first sidewall of the channel layer 630 may be formed to implement a single gate transistor structure.

The gate electrode 640 may include doped poly silicon, metal, conductive metal nitride, conductive metal silicide, conductive metal oxide, or a combination thereof. For example, the gate electrode 640 may be formed of doped poly silicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but is not limited thereto.

The gate insulating layer 650 may surround the sidewalls of the channel layer 630 and may be interposed between the channel layer 630 and the gate electrode 640. For example, as illustrated in FIG. 9A, all of the sidewalls of the channel layer 630 may be surrounded by the gate insulating layer 650, and a portion of a sidewall of the gate electrode 640 may make contact with the gate insulating layer 650. In other embodiments, the gate insulating layer 650 may extend in the extension direction of the gate electrode 640 (that is, in the first direction (the X direction)), and only two sidewalls facing the gate electrode 640 among the sidewalls of the channel layer 630 may make contact with the gate insulating layer 650.

In some embodiments, the gate insulating layer 650 may be formed of a silicon oxide film, a silicon oxy nitride film, a high-k dielectric film having a higher dielectric constant than the silicon oxide film, or a combination thereof. The high-k dielectric film may be made of metal oxide or metal oxy nitride. For example, a high-k dielectric film that is able to be used as the gate insulating layer 650 may be made of HfO₂, HfSiO, HIfSiON, HfTaO, HfTiO, HfZrO, ZrO₂, Al₂O₃, or a combination thereof, but is not limited thereto.

A plurality of second insulating patterns 632 may extend in the second direction (the Y direction) on the plurality of first insulating patterns 622, and the channel layer 630 may be disposed between two adjacent second insulating patterns 632 among the plurality of second insulating patterns 632. In addition, between the two adjacent second insulating patterns 632, a first buried layer 634 and a second buried layer 636 may be disposed in the space between two adjacent channel layers 630. The first buried layer 634 may be disposed on the bottom of the space between the two adjacent channel layers 630, and the second buried layer 636 may be formed on the first buried layer 634 to fill the rest of the space between the two adjacent channel layers 630. The upper surface of the second buried layer 636 may be disposed at the same level as the upper surface of the channel layer 630, and the second buried layer 636 may cover the upper surface of the gate electrode 640. Alternatively, the plurality of second insulating patterns 632 may be formed as a material layer continuous with the plurality of first insulating patterns 622, or the second buried layer 636 may be formed as a material layer continuous with the first buried layer 634.

Capacitor contacts 660 may be disposed on the channel layers 630. The capacitor contacts 660 may be disposed to vertically overlap the channel layers 630 and may be arranged in a matrix form in which the capacitor contacts 660 are spaced apart from each other in the first direction (the X direction) and the second direction (the Y direction). The capacitor contacts 660 may be formed of doped poly silicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but are not limited thereto. An upper insulating layer 662 may be disposed on the plurality of second insulating patterns 632 and the second buried layer 636 to surround the sidewalls of the capacitor contacts 660.

An etch stop layer 670 may be disposed on the upper insulating layer 662, and the capacitor structure 680 may be disposed on the etch stop layer 670. The capacitor structure 680 may include lower electrodes 682, a capacitor dielectric layer 684, and an upper electrode 686.

The lower electrodes 682 may penetrate the etch stop layer 670 and may be electrically connected to the upper surfaces of the capacitor contacts 660. The lower electrodes 682 may be formed in a pillar type extending in the third direction (the Z direction), but are not limited thereto. In some embodiments, the lower electrodes 682 may be disposed to vertically overlap the capacitor contacts 660 and may be arranged in a matrix form in which the lower electrodes 682 are spaced apart from each other in the first direction (the X direction) and the second direction (the Y direction). Alternatively, landing pads (not illustrated) may be additionally disposed between the capacitor contacts 660 and the lower electrodes 682, and the lower electrodes 682 may be arranged in a hexagonal shape.

FIG. 9D is a view illustrating the layout of a cell array mat 110B according to an embodiment of the present disclosure, and FIG. 9E is a perspective view illustrating the cell array mat 110B of FIG. 9D according to example embodiments.

Referring to FIGS. 9D and 9E, the cell array mat 110B may include a substrate 610A, a plurality of first conductive lines 620A, channel structures 630A, contact gate electrodes 640A, a plurality of second conductive lines 642A, and a capacitor structure 680. The cell array mat 110B may include a vertical channel transistor.

A plurality of active areas AC may be defined on the substrate 610A by a first device isolation film 612A and a second device isolation film 614A. The channel structures 630A may be disposed in the active areas AC, respectively. Each of the channel structures 630A may include a first active pillar 630A1 and a second active pillar 630A2 that extend in the vertical direction and a connecting portion 630L connected to the bottom of the first active pillar 630A1 and the bottom of the second active pillar 630A2. A first source/drain area SD1 may be disposed in the connecting portion 630L, and a second source/drain area SD2 may be disposed at the tops of the first and second active pillars 630A1 and 630A2. Each of the first active pillar 630A1 and the second active pillar 630A2 may constitute an independent unit memory cell.

The plurality of first conductive lines 620A may extend in a direction crossing the plurality of active areas AC, for example, in the second direction (the Y direction). One first conductive line 620A among the plurality of first conductive lines 620A may be disposed on the connecting portion 630L between the first active pillar 630A1 and the second active pillar 630A2. The one first conductive line 620A may be disposed on the first source/drain area SD1. Another first conductive line 620A adjacent to the one first conductive line 620A may be disposed between two channel structures 630A. One first conductive line 620A among the plurality of first conductive lines 620A may function as a common bit line included in two unit memory cells constituted by the first active pillar 630A1 and the second active pillar 630A2 disposed on the opposite sides of the one first conductive line 620A.

One contact gate electrode 640A may be disposed between two channel structures 630A adjacent to each other in the second direction (the Y direction). For example, the contact gate electrode 640A may be disposed between the first active pillar 630A1 included in one channel structure 630A and the second active pillar 630A2 included in the other channel structure 630A and may be shared by the first active pillar 630A1 and the second active pillar 630A2 disposed on the opposite sides of the contact gate electrode 640A. A gate insulating layer 650A may be disposed between the contact gate electrode 640A and the first active pillar 630A1 and between the contact gate electrode 640A and the second active pillar 630A2. The plurality of second conductive lines 642A may extend in the first direction (the X direction) on the upper surfaces of the contact gate electrodes 640A. The plurality of second conductive lines 642A may function as word lines of the cell array mat 110B.

Capacitor contacts 660A may be disposed on the channel structures 630. The capacitor contacts 660A may be disposed on the second source/drain areas SD2, and the capacitor structure 680 may be disposed on the capacitor contacts 660A.

Meanwhile, although not illustrated in FIGS. 9A to 9E, according to an embodiment of the present disclosure, a plurality of metal layers may be formed under the cell array mats 110A and 110B.

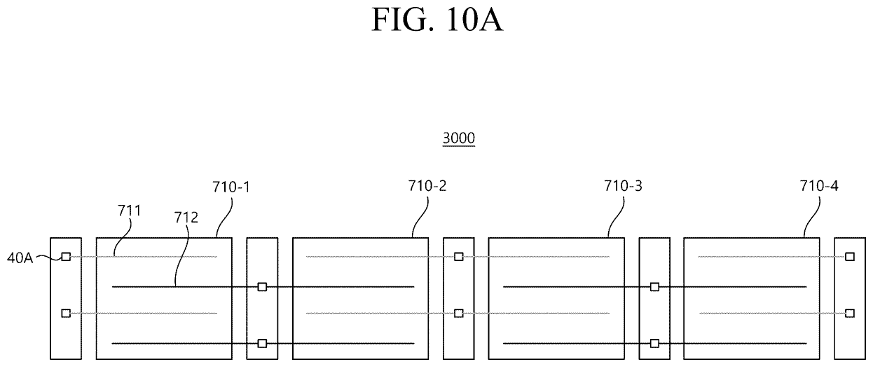

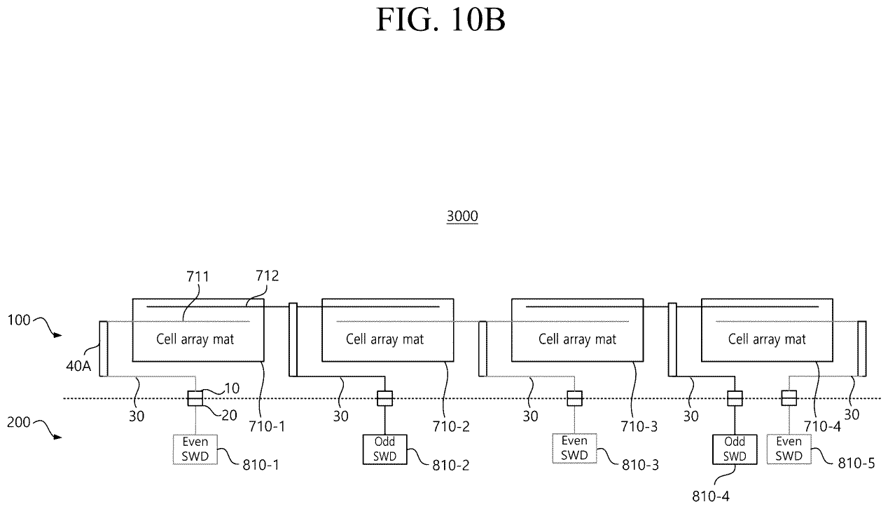

FIG. 10A is a schematic plan view illustrating a portion of a semiconductor memory device 3000 according to an embodiment of the present disclosure, and FIG. 10B is a sectional view corresponding to the plan view of FIG. 10A according to example embodiments.

Referring to FIGS. 10A and 10B together, the semiconductor memory device 3000 may include first to fourth cell array mats 710-1, 710-2, 710-3, and 710-4. In addition, the semiconductor memory device 3000 may include first to fifth sub-word line drivers 810-1, 810-2, 810-3, 810-4, and 810-5 disposed under the first to fourth cell array mats 710-1, 710-2, 710-3, and 710-4 as illustrated.

The first to fourth cell array mats 710-1, 710-2, 710-3, and 710-4 may be included in the above-described first chip 100, and the first to fifth sub-word line drivers 810-1, 810-2, 810-3, 810-4, and 810-5 may be included in the above-described second chip 200. The first chip 100 and the second chip 200 may have a CoP structure in which the first chip 100 is stacked on the second chip 200. According to an embodiment, the first chip 100 and the second chip 200 may be electrically connected to each other by bonding first bonding metals 10 formed at the bottom of the first chip 100 and second bonding metals 20 formed at the top of the second chip 200.

Each of the first to fourth cell array mats 710-1, 710-2, 710-3, and 710-4 may include even word lines 711 and odd word lines 712 of a corresponding cell array mat.

The first to fifth sub-word line drivers 810-1, 810-2, 810-3, 810-4, and 810-5 may generate drive signals applied to the first to fourth cell array mats 710-1, 710-2, 710-3, and 710-4. The first to fifth sub-word line drivers 810-1, 810-2, 810-3, 810-4, and 810-5 may include, for example, the sub-word line drivers 810-1 and 810-5, each of which is in charge of one cell array mat, and the sub-word line drivers 810-2, 810-3, and 810-4, each of which is in charge of two adjacent cell array mats.

The drive signals generated from the first to fifth sub-word line drivers 810-1, 810-2, 810-3, 810-4, and 810-5 may be transferred to the first chip 100 through the first and second bonding metals 10 and 20. Each of the drive signals transferred to the first chip 100 may be transferred to one of opposite sides of the corresponding cell array mat 710-1, 710-2, 710-3, or 710-4 through a lower metal layer 30 of the first chip 100. The drive signals transferred to the cell array mats 710-1, 710-2, 710-3, and 710-4 may be applied to the word lines 711 and 712 of the first to fourth cell array mats 710-1, 710-2, 710-3, and 710-4 through VIAs 40A as illustrated.

In an embodiment, each lower metal layer 30 connected between a corresponding first bonding metal 10 and a corresponding VIA 40A may have a similar pattern to each other for reducing a word line loading difference.

In this case, the semiconductor memory device 3000 differs from the semiconductor memory device 50A described above with reference to FIGS. 3A and 3B in that the sub-word line drivers 810-1, 810-2, 810-3, 810-4, and 810-5 are disposed under the cell array mats 710-1, 710-2, 710-3, and 710-4.

Although it has been described that the first chip 100 and the second chip 200 that form the CoP structure are electrically connected to each other by bonding, embodiments are not limited thereto. According to an embodiment of the present disclosure, the first chip 100 and the second chip 200 may be electrically connected to each other through the through silicon via (TSV) method.

In this case, for example, a drive signal generated by the first sub-word line driver 210-1 or 810-1 of the second chip 200 described above may be transferred to the first chip 100 through one of a plurality of TSVs formed between the first chip 100 and the second chip 200 and may be applied to the first word lines 111 or 711 of the first and second cell array mats 110-1 or 710-1 and 110-2 or 710-2. In addition, a drive signal generated by the second sub-word line driver 210-2 or 810-2 may be transferred to the first chip 100 through another TSV formed between the first chip 100 and the second chip 200 and may be applied to the second word lines 112 or 712 of the first and second cell array mats 110-1 or 710-1 and 110-2 or 710-2.

Although it has been described that two chips, that is, the first chip 100 and the second chip 200 form the CoP structure, embodiments are not limited thereto. In example embodiments, three or more chips may be stacked to implement a semiconductor memory device having a CoP structure. Specifically, according to an embodiment of the present disclosure, at least one chip having memory cell arrays implemented therein and at least one chip having core/peri circuits implemented therein may be stacked to implement a semiconductor memory device having a CoP structure.

According to the various embodiments of the present disclosure described above, the sub-word line drivers may be appropriately arranged, and thus the characteristics of the semiconductor memory devices may be improved.

According to the various embodiments of the present disclosure described above, the performance of the semiconductor memory devices may be improved by appropriately arranging the sub-word line drivers.

While the present disclosure has been described with reference to embodiments thereof, it will be apparent to those of ordinary skill in the art that various changes and modifications may be made thereto without departing from the spirit and scope of the present invention as set forth in the following claims.

What is claimed is:

1. A semiconductor memory device comprising:
a first chip including a first cell array mat and a second cell array mat adjacent to the first cell array mat, each of the first and second cell array mats including first word lines and second word lines; and
a second chip having a stacked structure with the first chip, the second chip including:
a first sub-word line driver configured to generate a first drive signal applied to the first word lines from one side of each of the first and second cell array mats, and
a second sub-word line driver configured to generate a second drive signal applied to the second word lines from an opposite side of each of the first and second cell array mats.

2. The semiconductor memory device of claim 1, wherein the second chip is disposed under the first chip, and
wherein the first and second sub-word line drivers are located under the first and second cell array mats, respectively.

3. The semiconductor memory device of claim 2, wherein the first sub-word line driver is disposed in a portion of an area of the second chip configured to overlap an area in which the first cell array mat is formed, and
wherein the second sub-word line driver is disposed in a portion of an area of the second chip configured to overlap an area in which the second cell array mat is formed.

4. The semiconductor memory device of claim 2, wherein the first chip and the second chip are electrically connected to each other by bonding a first bonding metal formed at a bottom of the first chip and a second bonding metal formed at a top of the second chip, and
wherein the first and second drive signals are transferred to the first chip through the bonded first and second bonding metals.

5. The semiconductor memory device of claim 4, wherein materials of the first and second bonding metals include copper.

6. The semiconductor memory device of claim 1, wherein the first drive signal is applied to the first word lines of the first and second cell array mats through VIAs formed on opposite sides of the first cell array mat, and
wherein the second drive signal is applied to the second word lines of the first and second cell array mats through VIAs formed on opposite sides of the second cell array mat.

7. The semiconductor memory device of claim 6, wherein the first chip further includes a plurality of metal layers formed below the first and second cell array mats, and
wherein the first and second drive signals are transferred to the VIAs formed on the opposite sides of the first and second cell array mats through one metal layer among the plurality of metal layers.

8. The semiconductor memory device of claim 7, wherein the plurality of metal layers include a copper layer and a tungsten layer, and
wherein the first and second drive signals are transferred to the VIAs formed on the opposite sides of the first and second cell array mats through the tungsten layer.

9. The semiconductor memory device of claim 1, wherein each of the first and second cell array mats includes a plurality of memory cells disposed in areas in which the first and second word lines cross a plurality of bit lines, and
wherein each of the plurality of memory cells includes a vertical channel transistor.

10. The semiconductor memory device of claim 9, wherein each of the first and second sub-word line drivers include one or more horizontal channel transistors.

11. The semiconductor memory device of claim 1, wherein the first word lines and the second word lines are alternately arranged in each of the first and second cell array mats.

12. The semiconductor memory device of claim 1, wherein the first chip includes a plurality of cell array mats in which the first and second cell array mats are repeated,
wherein the second chip includes a plurality of sub-word line drivers in which the first and second sub-word line drivers are repeated, and
wherein the plurality of sub-word line drivers have the same driving strength.

13. The semiconductor memory device of claim 12, wherein the plurality of sub-word line drivers have the same word line loading.

14. A semiconductor memory device comprising:
a plurality of cell array mats implemented in a first chip, each cell array mat including a plurality of word lines; and
a plurality of sub-word line drivers implemented in a second chip having a stacked structure with the first chip and disposed to correspond to the plurality of cell array mats, respectively,
wherein the plurality of sub-word line drivers are configured to generate drive signals applied to the plurality of word lines of the plurality of cell array mats,
wherein a first drive signal of the drive signals is applied to even word lines among the plurality of word lines from one side of a corresponding cell array mat, and
wherein a second drive signal of the drive signals is applied to odd word lines among the plurality of word lines from an opposite side of the corresponding cell array mat.

15. The semiconductor memory device of claim 14, wherein the second chip is disposed under the first chip, and
wherein the plurality of sub-word line drivers are located under the plurality of cell array mats, respectively.

16. The semiconductor memory device of claim 14, wherein the plurality of sub-word line drivers include:
a first sub-word line driver configured to generate the first drive signal applied to the even word lines, and
a second sub-word line driver configured to generate the second drive signal applied to the odd word lines.

17. The semiconductor memory device of claim 16, wherein the plurality of cell array mats include a first cell array mat and a second cell array mat adjacent to each other, and
wherein the first and second sub-word line drivers are disposed under the first and second cell array mats, respectively.

18. The semiconductor memory device of claim 17, wherein each of the plurality of cell array mats includes the even word lines and the odd word lines,
wherein the first drive signal is transferred to opposite sides of the first cell array mat, and
wherein the second drive signal is transferred to opposite sides of the second cell array mat.

19. The semiconductor memory device of claim 18, wherein the plurality of cell array mats further include a third cell array mat adjacent to the second cell array mat and a fourth cell array mat adjacent to the third cell array mat,
wherein the plurality of sub-word line drivers further include a third sub-word line driver configured to generate a third drive signal applied to the even word lines of the third and fourth cell array mats, and a fourth sub-word line driver configured to generate a fourth drive signal applied to the odd word lines of the third and fourth cell array mats,
wherein the third and fourth sub-word line drivers are disposed under the third and fourth cell array mats, respectively,
wherein the third drive signal is transferred to opposite sides of the third cell array mat,
wherein the fourth drive signal is transferred to opposite sides of the fourth cell array mat, and
wherein the first and third sub-word line drivers are configured to generate the first and third drive signals in response to a first row address, and the second and fourth sub-word line drivers are configured to generate the second and fourth drive signals in response to a second row address.

20. A semiconductor memory device having a cell on periphery (CoP) structure, the semiconductor memory device comprising:
a first chip including a plurality of cell array mats, each of which includes a plurality of word lines; and
a second chip including a plurality of sub-word line drivers disposed under the plurality of cell array mats, respectively,
wherein the plurality of sub-word line drivers are configured to generate drive signals, wherein the plurality of word lines include even word lines to which a first drive signal of the drive signals is applied from one side of a corresponding cell array mat and odd word lines to which a second drive signal of the drive signals is applied from an opposite side of the corresponding cell array mat, and
wherein the plurality of sub-word line drivers include first and second sub-word line drivers corresponding to two adjacent cell array mats configured to respectively generate the first drive signal applied to the even word lines of the two adjacent cell array mats and the second drive signal applied to the odd word lines of the two adjacent cell array mats.
